(19) United States
(12) Patent Application Publication
(10) Pub. No.: US 2024/0274751 A1
(43) Pub. Date: Aug. 15, 2024

(54) RED-LIGHT-EMITTING SEMICONDUCTOR LIGHT-EMITTING DEVICE AND METHOD FOR MANUFACTURING SAME

(71) Applicant: LG ELECTRONICS INC., Seoul (KR)

(72) Inventors: Dongwook KIM, Seoul (KR); Sukkoo JUNG, Seoul (KR); Daesung KANG, Seoul (KR); Donghun KANG, Seoul (KR)

(73) Assignee: LG ELECTRONICS INC., Seoul (KR)

(21) Appl. No.: 18/566,943

(22) PCT Filed: Jun. 7, 2021
(86) PCT No.: PCT/KR2021/007069

§ 371 Date: Dec. 4, 2023

(51) Int. Cl. H01L 33/12; H01L 33/00; H01L 33/06; H01L 33/30

(52) U.S. Cl. CPC H01L 33/12; H01L 33/0062; H01L 33/06; H01L 33/30

(57) ABSTRACT

The present disclosure relates to a red-light-emitting semiconductor light-emitting device, which is applicable to a technical field related to a display device, for example, can be used in a display device, and to a method for manufacturing same. The present disclosure may comprise: a substrate; a buffer layer located on the substrate; a first conductive contact layer located on the buffer layer; a first conductive constraint layer located on the first conductive contact layer; an active layer located on the first conductive constraint layer; a second conductive constraint layer located on the active layer; and a current concentration structure located on at least one side of between the first conductive contact layer and the first conductive constraint layer and between the second conductive contact layer and the second conductive constraint layer. In this case, the current concentration structure may include: a lattice strain induction layer; and a high resistance layer which is in contact with the lattice strain induction layer, separated from the lattice strain induction layer, and distributed to form a current barrier.

### TECHNICAL FIELD

The present disclosure is applicable to a display device-related technical field and relates to, for example, a red light-emitting semiconductor light-emitting device usable in a display device and a method of manufacturing the same.

### BACKGROUND ART

Recently, in a field of a display technology, display devices having excellent characteristics such as thinness, flexibility, and the like have been developed. On the other hand, currently commercialized major displays are represented by an LCD (liquid crystal display) and an OLED (organic light emitting diode).

An LED (light emitting diode), which is a well-known semiconductor light-emitting element that converts electric current into light, has been used as a light source for a display image of an electronic device including an information and communication device along with a GaP:N-based green LED, starting with commercialization of a red LED using a GaAsP compound semiconductor in 1962.

Recently, LEDs have become increasingly miniaturized, with micrometer-sized LEDs being fabricated and used as pixels in display devices.

Compared to other display devices/panels, this micro-LED technology exhibits the characteristics of low power, high brightness, and high reliability, and is applicable even to flexible devices. Therefore, it has been actively researched by research institutes and companies in recent years.

A micro-LED tends to have low external quantum efficiency relative to a light-emitting device of a relatively large size.

In general, the micro-LED may have reduced luminous efficiency due to non-emission at the sidewall thereof. In particular, at low current in the early stage of operation, carriers may severely leak, causing deterioration in luminance of the device. This phenomenon is especially noticeable in the case of a red light-emitting device.

Due to these non-linear magnitude-current (L-I) characteristics at low current, when the red light-emitting device is used in a display, i.e., when the red light-emitting device is used in a so-called micro-LED display, gradation for expressing colors in the display may be non-uniform.

The reasons why external quantum efficiency (EQE) decreases depending on the size of a light-emitting device chip may be summarized as follows.

1. Due to the influence of sidewall defects of the light-emitting device chip, as the size of the light-emitting device chip becomes smaller, the ratio of a sidewall with many defects to the entire area of the chip relatively increases. Accordingly, dangling bonds may increase.

In other words, as a surface-to-volume ratio increases, a possibility that initially supplied carriers required for light emission at low current are captured by sidewall defects and fail to contribute to light emission may increase. These characteristics may be common features of an ultra-small chip such as the micro-LED.

2. (Al,Ga,In)P, as a material used to fabricate a thin film of the red light-emitting device, has a higher surface recombination velocity (SRV) than GaN, or InGaN, as a material used in a blue/green light-emitting device, and thus, the initial loss of carriers may increase. Therefore, the red light-emitting device may be more disadvantageous than the blue/green light-emitting device in terms of low-current EQE characteristics.

When comparing the SRV of InGaN used in the blue/green light-emitting device with the SRV of AlGalnP used in the red light-emitting device, the SRV of InGaN is approximately 1×10¹⁴ cm and the SRV of AlGalnP is approximately 1×10¹⁵ cm, which is a difference of about 1 order of magnitude.

3. When miniaturizing the light-emitting device chip, dry or wet etching is performed for dicing (isolation) to separate and mold the chip. In this case, the rate of damage at the sidewall of the light-emitting device chip increases. To compensate for this, a method of optimizing heat treatment or a passivation layer may be used.

Accordingly, a method capable of improving characteristics in which EQE is degraded in such an ultra-small light-emitting device chip is needed.

### DISCLOSURE

### Technical Problem

The present disclosure provides a red light-emitting semiconductor light-emitting device that increases current density in an ultra-small red light-emitting device and a method of manufacturing the same.

In addition, the present disclosure provides a red light-emitting semiconductor light-emitting device that reduces SRV, which is noticeable in an ultra-small light-emitting device chip, by suppressing a flow of carriers leaking to the sidewall of the light-emitting device, and a method of manufacturing the same.

In addition, the present disclosure provides a red light-emitting semiconductor light-emitting device in which internal carriers induced in a vertical direction additionally contribute to low-current radiative recombination, thereby improving low-current characteristics, and a method of manufacturing the same.

### Technical Solution

According to an aspect of the present disclosure, provided herein is a red light-emitting semiconductor light-emitting device, including: a substrate; a buffer layer disposed on the substrate: a first conductive contact layer disposed on the buffer layer; a first conductive confinement layer disposed on the first conductive contact layer; an active layer disposed on the first conductive confinement layer; a second conductive confinement layer disposed on the active layer: a second conductive contact layer disposed on the second conductive confinement layer; and a current concentration structure disposed at least one side between the first conductive contact layer and the first conductive confinement layer or between the second conductive contact layer and the second conductive confinement layer.

The current concentration structure may include a strain induced layer; and high-resistance layers that contact the strain induced layer and are distributed separately from each other to form a current barrier.

The strain induced layer may include a semiconductor layer subjected to tensile strain.

The strain induced layer may include a material of (AlₓGa₁₋ₓ)_{1-y}In_{y}P.

Here, y may be less than 0.48.

The strain induced layer may have a thickness of 10 nm or more.

The high-resistance layers may include a segregation structure.

The segregation may include any one of aluminum (Al), gallium (Ga), and indium (In).

The high-resistance layers may be formed by segregating at least one of indium (In), aluminum (Al), or gallium (Ga) in contact with the strain induced layer.

The segregation may be disposed inside a layer adjacent to the active layer.

The high-resistance layers may be formed by artificial strain relaxation.

The high-resistance layers may be further included in the active layer.

The current concentration structure may be disposed adjacent to the active layer.

In another aspect of the present disclosure, provided herein is a method of manufacturing a red light-emitting semiconductor light-emitting device, including: forming a buffer layer on a substrate: forming a first conductive contact layer on the buffer layer: forming a first strain induced layer on the first conductive contact layer, a lattice constant of the first strain induced layer being different from a lattice constant of the first conductive contact layer: forming a first high-resistance layer in contact with the first strain induced layer by forming a first conductive confinement layer on the first strain induced layer, the first conductive confinement layer having a lattice constant that applies strain to the first strain induced layer; forming an active layer on the first conductive confinement layer: forming a second conductive confinement layer on the active layer; and forming a second conductive contact layer on the second conductive confinement layer.

The method may further include forming a second strain induced layer on the second conductive confinement layer.

The second strain induced layer may be formed to have a strain critical thickness or more to form a second high-resistance layer in contact with the second strain induced layer.

The second conductive contact layer may have a smaller lattice constant than the second strain induced layer.

The method may further include forming a current diffusion layer between the second conductive confinement layer and the second strain induced layer.

At least one of the first strain induced layer or the second strain induced layer may include a semiconductor layer subjected to tensile strain.

At least one of the first strain induced layer or the second strain induced layer may include a material of (AlₓGa₁₋ₓ)_{1-y}In_{y}P.

At least one of the first high-resistance layer or the second high-resistance layer may include a segregation structure.

### Advantageous Effects

According to an embodiment of the present disclosure, the following effects are achieved.

First, a current concentration structure according to an embodiment of the present disclosure serves as a barrier against horizontal movement and vertical (injection) movement of n-type and p-type carriers (electrons and holes), thereby suppressing and inducing a current path inside a thin film.

Therefore, current is concentrated in an area with relatively low resistance when the same current is applied, thereby increasing current density.

In particular, SRV, which is noticeable in an ultra-small light-emitting device chip, may be reduced by suppressing a flow of carriers leaking to the sidewall of a light-emitting device. In addition, internal carriers induced in a vertical direction may additionally contribute to low-current radiative recombination, so that low-current characteristics may be improved.

In addition, a segregation disposed on the edge of the light-emitting device may prevent a significant number of carriers from being captured on the surface of the light-emitting device.

Furthermore, according to another embodiment of the present disclosure, there are additional technical effects not mentioned herein. Those skilled in the art may understand the technical effects through the entire contents of the specification and drawings.

### BRIEF DESCRIPTION OF DRAWINGS

FIG. 1 is a cross-sectional schematic diagram illustrating a red semiconductor light-emitting device according to an embodiment of the present disclosure.

FIG. 2 is a conceptual diagram illustrating a current concentration structure of a red semiconductor light-emitting device according to an embodiment of the present disclosure.

FIG. 3 is a photograph illustrating a current concentration structure of a red semiconductor light-emitting device according to an embodiment of the present disclosure.

FIG. 4 is a graph illustrating a current characteristic of a general red semiconductor light-emitting device.

FIG. 5 is a graph illustrating a current characteristic of an ultra-small semiconductor light-emitting device.

FIG. 6 is a graph illustrating external quantum efficiency according to chip size of a red semiconductor light-emitting device.

FIG. 7 is a conceptual diagram illustrating a general red semiconductor light-emitting device as a comparative example.

FIG. 8 is a conceptual diagram illustrating another example of a current concentration structure of a red semiconductor light-emitting device according to an embodiment of the present disclosure.

FIG. 9 is a graph illustrating external quantum efficiency according to the current density of each of the light-emitting devices illustrated in FIGS. 7 and 8.

FIG. 10 is a conceptual diagram illustrating a current concentration structure of a red semiconductor light-emitting device according to another embodiment of the present disclosure.

FIG. 11 is a conceptual diagram illustrating a current concentration structure of a red semiconductor light-emitting device according to another embodiment of the present disclosure.

FIG. 12 is a cross-sectional view illustrating an implementation example of a red semiconductor light-emitting device according to an embodiment of the present disclosure.

FIG. 13 is a cross-sectional view illustrating another implementation example of a red semiconductor light-emitting device according to an embodiment of the present disclosure.

FIG. 14 is a flowchart illustrating a method of manufacturing a red semiconductor light-emitting device according to an embodiment of the present disclosure.

FIGS. 15 to 19 are cross-sectional schematic diagrams illustrating a method of manufacturing a red semiconductor light-emitting device according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light-emitting device mentioned in this specification is a concept including an LED, a micro-LED, and the like, and they may be used interchangeably.

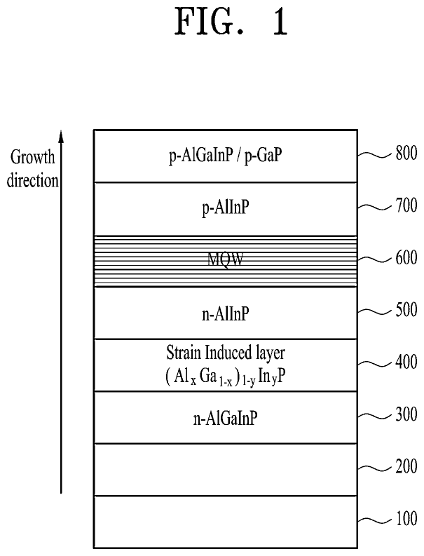

FIG. 1 is a cross-sectional schematic diagram illustrating a red semiconductor light-emitting device according to an embodiment of the present disclosure.

Referring to FIG. 1, the red semiconductor light-emitting device according to an embodiment of the present disclosure includes a buffer layer 200, first conductive semiconductor layers 300 and 500, an active layer 600, and second conductive layers 700 and 800, which are sequentially disposed on a substrate 100.

The substrate 100 may include a gallium arsenide (GaAs) substrate. For example, the substrate 100 may be a thick GaAs substrate.

Here, as an example, a first conductivity may be n-type and a second conductivity may be p-type. Hereinafter, an embodiment of the present disclosure will be described by taking an example in which the first conductivity is n-type and the second conductivity is p-type.

The red semiconductor light-emitting device may be formed of a quaternary material of group III elements and group V elements. For example, the group III elements may include aluminum (Al), gallium (Ga), and indium (In), and the group V elements may include phosphorus (P). This red semiconductor light-emitting device may also form a binary or ternary material of the group III elements and the group V elements.

For example, the red semiconductor light-emitting device according to an embodiment of the present disclosure may be formed by selectively combining materials of Al, Ga, In, and P. That is, the red semiconductor light-emitting device may include a binary material such as AlP, GaP, or InP, a ternary material such as AlGaP or AlInP, and a quaternary material such as AlGalnP. Meanwhile, in some cases, arsenic (As) may be used instead of indium (P).

An n-type semiconductor layer may include the n-type contact layer 300 and the n-type confinement layer 500 disposed on the n-type contact layer 300.

For example, the n-type contact layer 300 may include a quaternary material of AlGaInP doped with silicon (Si) as a dopant. This n-type contact layer 300 may also serve as a current diffusion layer.

The n-type confinement layer 500 may include a ternary material of n-AlInP having a relatively large bandgap energy. This n-type confinement layer 500 may be doped with Si as a dopant.

A current concentration structure 400 including a strain-induced layer (SIL) 410 may be positioned between the n-type contact layer 300 and the n-type confinement layer 500.

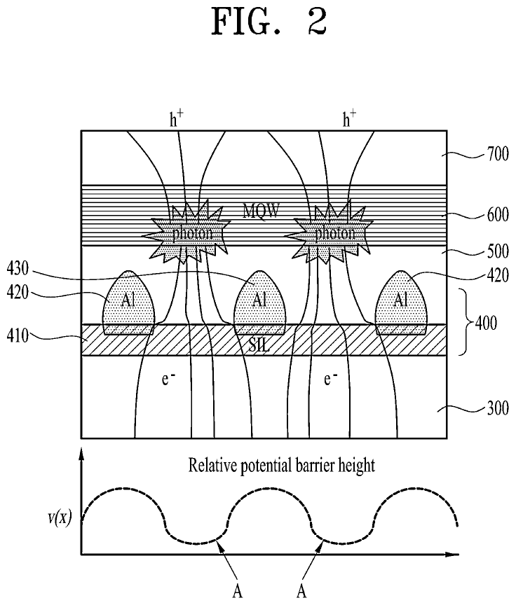

FIG. 2 is a conceptual diagram illustrating a current concentration structure of a red semiconductor light-emitting device according to an embodiment of the present disclosure.

Referring to FIG. 2, a current concentration structure 400 includes an SIL 410, and high-resistance layers 420 and 430 that contact the SIL 410 and are distributed separately from each other to form current barriers.

This SIL 410 may include a semiconductor layer subjected to tensile strain. That is, the SIL 410 may include a layer having a relatively small lattice constant.

For example, a lattice constant of the SIL 410 may be smaller than that of an n-type contact layer 300. An n-type confinement layer 500 formed thereafter may have a larger lattice constant than the SIL 410. For example, the lattice constant of the n-type confinement layer 500 may be the same as or similar to that of the n-type contact layer 300.

In this case, as the n-type confinement layer 500 formed on the SIL 410 grows, lattice defects may occur in order to achieve lattice matching between the n-type contact layer 300, the SIL 410, and the n-type confinement layer 500. Due to these lattice defects, a partial segregation phenomenon of the group III elements (Al, Ga, and In) may occur.

This SIL 410 may include (AlₓGa₁₋ₓ)_{1-y}In_{y}P. For example, the SIL 410 may be formed of a quaternary material of AlGalnP, i.e., (AlₓGa₁₋ₓ)_{1-y}In_{y}P.

In this case, the content of In, i.e., the value of y, may be less than 0.48. That is, in order to function as the SIL 410 or to generate the partial segregation phenomenon of the group III elements (Al, Ga, and In) due to lattice defects, the value of y may be less than 0.48. More specifically, the value of y may be 0.3 to 0.35.

In addition, in order to serve as the SIL 410, or to generate the partial segregation phenomenon of the group III elements (Al, Ga, and In) due to the lattice defects, the thickness of the SIL 410 may be 10 nm or more. This thickness may be a thickness for relaxing strain acting on the SIL 410.

As such, since there are layers with relatively large lattices on an upper portion and a lower portion of the SIL 410, the SIL 410 itself is subjected to tensile strain. In this case, when the thickness of the SIL 410 exceeds a critical thickness, the lattices are broken and the strain is released. This state may be referred to as a strain-relaxed state.

In this state, a form of defects, i.e., segregations of elements, may occur.

Such segregations 420 and 430 may form high-resistance layers. In other words, the segregations 420 and 430 may correspond to partial segregations of the group III elements (Al, Ga, and In). That is, the high-resistance layers 420 and 430 may be formed by artificial strain relaxation.

Hereinafter, the layers in which the segregations 420 and 430 are distributed may be referred to as high-resistance layers. Referring to FIG. 2, the segregations 420 and 430 may be distributed separately from each other. These segregations 420 and 430 may be distributed separately from each other in contact with the SIL 410.

As an example, FIG. 2 illustrates a state in which aluminum (Al) segregations 420 and 430 occur in contact with the SIL 410. These segregations may include the segregation 420 disposed on the edge side of the light-emitting device and the segregation 430 disposed on the inner side of the light-emitting device.

This segregations may include any one of Al, Ga, and In. For example, the high-resistance layers 420 and 430 may be formed by segregating at least one of In, Al, or Ga in contact with the SIL 410.

In this way, the high-resistance layers 420 and 430, i.e., the segregations may be disposed inside a layer adjacent to the active layer 600. In this case, the high-resistance layers 420 and 430 may be disposed inside the n-type confinement layer 500. In other words, the high-resistance layers 420 and 430 may be disposed between the SIL 410 and the active layer 600.

These high-resistance layers 420 and 430 may act as a barrier against a flow of current occurring between the n-type semiconductor layers 300 and 500 and the p-type semiconductor layers 700 and 800. This barrier against current may serve to suppress and induce an internal current flow.

In other words, the current concentration structure 400 including the high-resistance layers 420 and 430 may act as an (injection) barrier against horizontal movement and/or vertical movement of carriers including holes (h+) and electrons (e−) inside the semiconductor structure.

This current concentration structure 400 may have an effect of increasing current density by concentrating current in an area with relatively low resistance when the same current is applied.

Since the carriers including holes (h+) and electrons (e−) combine in the active layer 600 to emit photons, the current concentration structure 400 may be advantageously disposed close to the active layer 600 unless characteristics (photon performance/current leakage) of crystal quality of the semiconductor structure deteriorate.

In this case, a relative potential barrier height V(x) may appear to periodically rise and fall depending on the positions of the segregations 420 and 430, as shown in the lower part of FIG. 2.

That is, a low potential barrier may appear in a portion in which the segregations 420 and 430 are not located, i.e., a portion A disposed between the segregations 420 and 430.

Accordingly, current or carriers may move through the portion A disposed between the segregations 420 and 430 in which the low potential barrier is formed.

Meanwhile, referring again to FIG. 1, the p-type semiconductor layer may include the p-type confinement layer 700 and the p-type contact layer 800 disposed on the p-type confinement layer 700.

For example, the p-type confinement layer 700 may include a ternary material of n-AlInP having a relatively large bandgap energy. This p-type confinement layer 700 may be doped with magnesium (Mg) as a dopant.

For example, the p-type contact layer 800 may include a quaternary material of AlGalnP doped with Mg as a dopant. As another example, the p-type contact layer 800 may include a binary material of GaP doped with Mg as a dopant.

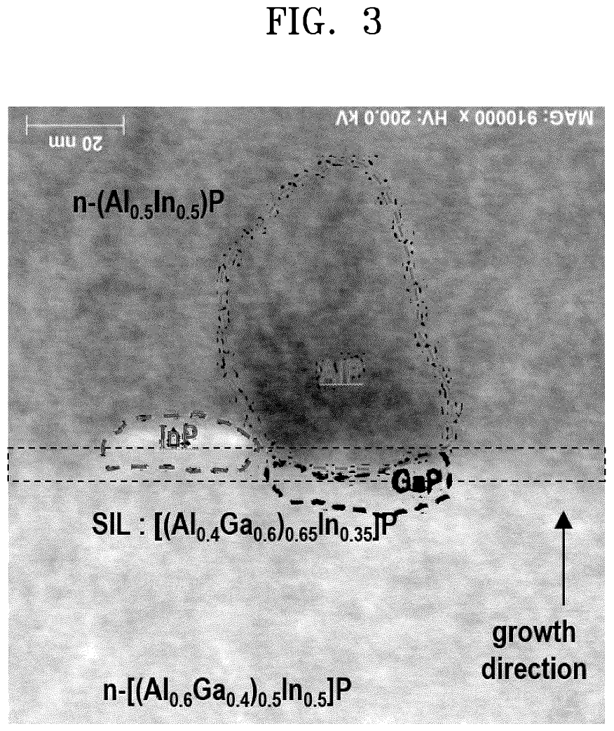

FIG. 3 is a photograph illustrating a current concentration structure of a red semiconductor light-emitting device according to an embodiment of the present disclosure.

Referring to FIG. 3 a state in which In, Ga, and Al are segregated in contact with the SIL 410 is illustrated.

These In, Ga, and Al segregations may exist in the form of InP, GaP, and AIP, respectively.

The In, Ga, and Al segregations may form the high-resistance layers 420 and 430 described above.

Referring to FIG. 3, the In, Ga, and Al segregations may be disposed inside the n-type confinement layer 500 formed of n-AlInP.

For example, in FIG. 3, an example in which the n-type contact layer 300 is formed of (Al_{0.6}Ga_{0.4})_{0.5}In_{0.5}P, and the content of In of the SIL 410 is 0.35 is illustrated. Additionally, the n-type confinement layer 500 may be formed of (Al_{0.4}Ga_{0.6})_{0.65}In_{0.35}P.

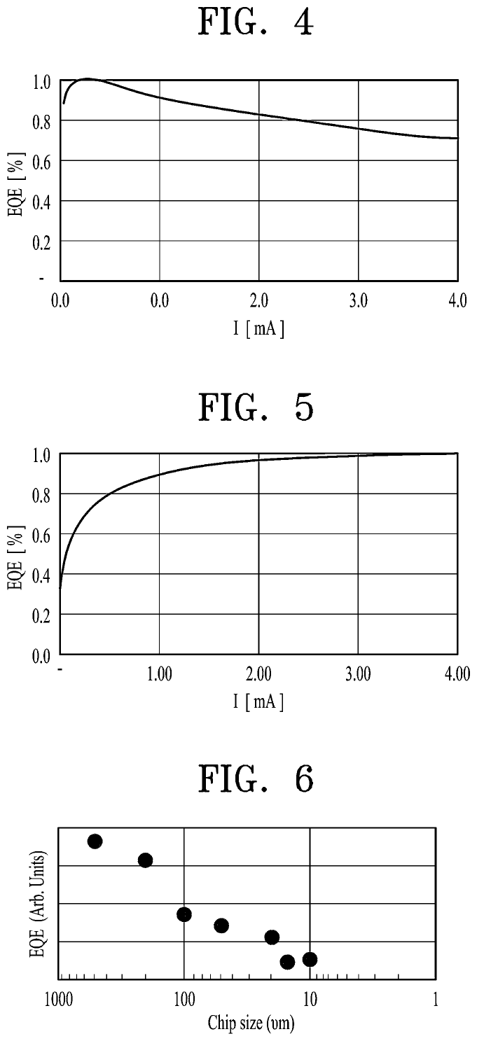

FIG. 4 is a graph illustrating a current characteristic of a general red semiconductor light-emitting device. FIG. 5 is a graph illustrating a current characteristic of an ultra-small semiconductor light-emitting device. FIG. 6 is a graph illustrating EQE according to chip size of a red semiconductor light-emitting device.

Referring to FIG. 5, a semiconductor light-emitting device (or light-emitting diode (LED)) having a diameter or long axis length of several to hundreds of micrometers (hereinafter, a micro-LED) tends to show lower EQE than EQE of a light-emitting device of a relatively large size illustrated in FIG. 4. EQE generally refers to the number of photons generated relative to injected carriers.

In general, the micro-LED may have reduced luminous efficiency due to non-emission at the sidewall thereof. In particular, at low current in the early stage of operation, carriers may severely leak, causing deterioration in luminance of the device. This phenomenon is especially noticeable in the case of a red light-emitting device.

Due to these non-linear magnitude-current (L-I) characteristics at low current, when the red light-emitting device is used in a display, i.e., when the red light-emitting device is used in a so-called micro-LED display, gradation for expressing colors in the display may be non-uniform.

Referring to FIG. 6, it may be seen that EQE decreases significantly depending on the size of a light-emitting device chip.

The reasons why EQE decreases depending on the size of the light-emitting device chip may be summarized as follows.

1. Due to the influence of sidewall defects of the light-emitting device chip, as the size of the light-emitting device chip becomes smaller, the ratio of a sidewall with many defects to the entire area of the chip relatively increases. Accordingly, dangling bonds may increase.

In other words, as a surface-to-volume ratio increases, a possibility that initially supplied carriers required for light emission at low current are captured by sidewall defects and fail to contribute to light emission may increase. These characteristics may be common features of an ultra-small chip such as the micro-LED.

2. (Al,Ga,In)P, as a material used to fabricate a thin film of the red light-emitting device, has a higher SRV than gallium nitride (GaN, or InGaN), as a material used in a blue/green light-emitting device, and thus, the initial loss of carriers may increase. Therefore, the red light-emitting device may be more disadvantageous than the blue/green light-emitting device in terms of low-current EQE characteristics.

When comparing the SRV of InGaN used in the blue/green light-emitting device with the SRV of AlGalnP used in the red light-emitting device, the SRV of InGaN is approximately 1×10¹⁴ cm and the SRV of AlGaInP is approximately 1×10¹⁵ cm, which is a difference of about 1 order of magnitude.

3. When miniaturizing the light-emitting device chip, dry or wet etching is performed for dicing (isolation) to separate and mold the chip. In this case, the rate of damage at the sidewall of the light-emitting device chip increases. To compensate for this, a method of optimizing heat treatment or a passivation layer may be used.

According to an embodiment of the present disclosure, characteristics in which EQE is degraded in such an ultra-small light-emitting device chip may be improved using the current concentration structure 400.

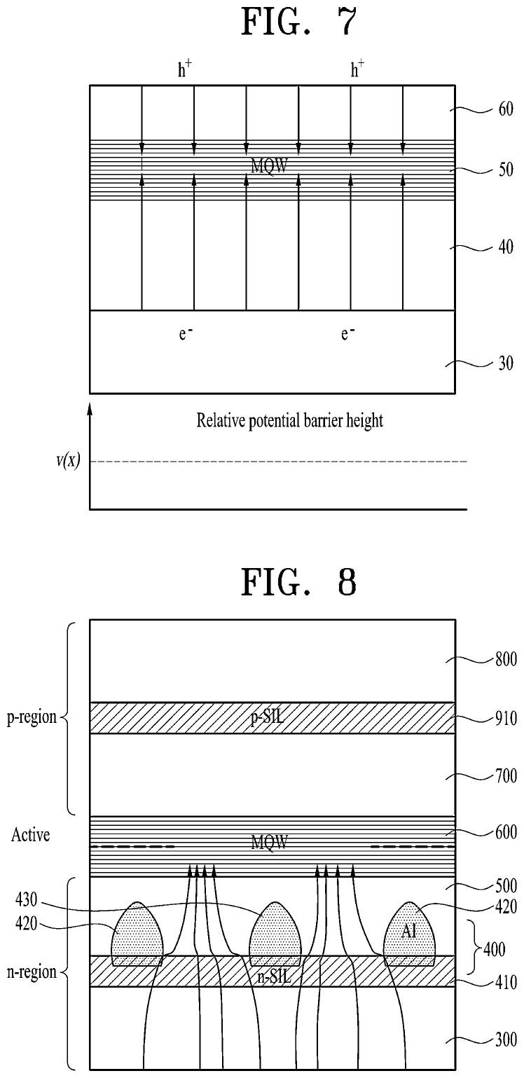

FIG. 7 is a conceptual diagram illustrating a general red semiconductor light-emitting device as a comparative example. FIG. 8 is a conceptual diagram illustrating another example of a current concentration structure of a red semiconductor light-emitting device according to an embodiment of the present disclosure. FIG. 9 is a graph illustrating EQE according to the current density of each of the light-emitting devices illustrated in FIGS. 7 and 8.

Referring to FIG. 7, the structure of a general red semiconductor light-emitting device to which the current concentration structure 400 as in an embodiment of the present disclosure is not applied is illustrated.

It may be appreciated that, in this general red semiconductor light-emitting device, the movement of carriers including holes (h+) and electrons (e−) is not restricted and the carriers move toward an active layer.

Therefore, a relative potential barrier height V(x) has a constant pattern depending on an area. Therefore, the carriers move without any special constraints. Many of these carriers may be captured on the surface of an ultra-small light-emitting device. In other words, EQE degradation characteristics described above may appear.

However, referring to FIG. 8, in the case of a red semiconductor light-emitting device including the current concentration structure 400, the current concentration structure 400 including the high-resistance layers 420 and 430 may function as an (injection) barrier against horizontal movement and/or vertical movement of carriers including holes (h+) and electrons (e−) inside a semiconductor structure.

Referring to FIG. 8, it may be appreciated that an SIL 910 may also be disposed in a p-region as well. The structure except for the SIL 910 may be the same as that of FIG. 2.

This current concentration structure 400 may have an effect of increasing current density by concentrating current in an area with relatively low resistance when the same current is applied.

Referring to FIG. 2 as well, the relative potential barrier height V(x) may appear to periodically rise and fall depending on the positions of the segregations 420 and 430.

Accordingly, current or carriers may move through the portion A disposed between the segregations 420 and 430 in which a low potential barrier is formed.

As described above, the segregations may include the segregation 420 disposed on the edge side of the light-emitting device and the segregation 430 disposed on the inner side of the light-emitting device. The segregation 420 disposed on the edge of the light-emitting device may specifically prevent a significant number of carriers from being captured on the surface of the light-emitting device.

Through this structure, when current is applied to the light-emitting device, the high-resistance layers (segregations 420 and 430) present at an interface (growth surface) act as a barrier against horizontal movement and vertical movement of n-type and p-type carriers (electrons and holes), thereby suppressing and inducing a current path inside a thin film.

Therefore, current is concentrated in an area with relatively low resistance when the same current is applied, which may have an effect of increasing current density.

In particular, SRV, which is noticeable in an ultra-small light-emitting device chip, may be reduced by suppressing a flow of carriers leaking to the sidewall of the light-emitting device. In addition, since internal carriers induced in a vertical direction may additionally contribute to low-current radiative recombination, low-current characteristics may be improved.

In this way, the current concentration structure 400 may act as a barrier against a flow of current occurring between the n-type semiconductor layers 300 and 500 and the p-type semiconductor layers 700 and 800. This barrier against current may serve to suppress and induce an internal current flow.

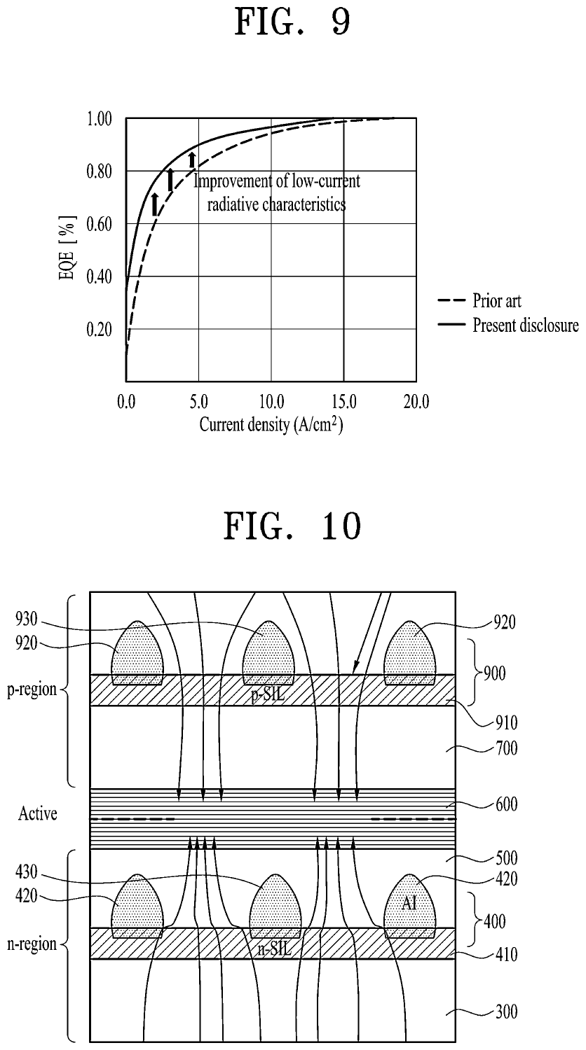

FIG. 10 is a conceptual diagram illustrating a current concentration structure of a red semiconductor light-emitting device according to another embodiment of the present disclosure.

Referring to FIG. 10, an embodiment of a light-emitting device including current concentration structures 400 and 900 in the n-type region and the p-type region, respectively, is illustrated. That is, the red semiconductor light-emitting device according to this embodiment may include the current concentration structure 900 even in the p-type region.

The current concentration structure 400 disposed in the n-type region may include an SIL 410 and high-resistance layers 420 and 430 that contact the SIL 410 and are distributed separately from each other to form current barriers.

The current concentration structure 400 disposed in the n-type region is the same as the structure described above with reference to FIG. 2, so a redundant description will be omitted.

A p-type confinement layer 700 may be disposed on an active layer 600.

For example, the p-type confinement layer 700 may include a ternary material of n-AlInP having a relatively large bandgap energy. This p-type confinement layer 700 may be doped with Mg as a dopant.

The current concentration structure 900 disposed in the p-type region may include an SIL 910 and high-resistance layers 920 and 930 that contact the SIL 910 and are distributed separately from each other to form current barriers.

This SIL 910 may include a semiconductor layer subjected to tensile strain. That is, the SIL 910 may include a layer having a relatively small lattice constant.

For example, a lattice constant of the SIL 910 may be smaller than that of the p-type confinement layer 700. In addition, a p-type contact layer 800 formed later on the current concentration structure 900 may have a smaller lattice constant than the SIL 910. For example, the lattice constant of the p-type contact layer 800 may be smaller than that of the p-type confinement layer 700. This p-type contact layer 800 may include, for example, a material of GaP.

Since the lattice constant of the SIL 910 is smaller than that of the p-type confinement layer 700, the SIL 910 may be subjected to tensile strain while growing. That is, lattice defects may occur in the SIL 910 in order to achieve lattice matching with the p-type confinement layer 700. A partial segregation phenomenon of group III elements (Al, Ga, and In) may occur due to these lattice defects.

This SIL 910 may include a material of (AlₓGa₁₋ₓ)_{1-y}In_{y}P. For example, the SIL 910 may be formed of a quaternary material of AlGalnP, i.e., (AlₓGa₁₋ₓ)_{1-y}In_{y}P.

In this case, the content of In, i.e., the value of y, may be less than 0.48. That is, in order to function as the SIL 910 or to generate the partial segregation phenomenon of the group III elements (Al, Ga, and In) due to lattice defects, the value of y may be less than 0.48. More specifically, the value of y may be 0.3 to 0.35.

In addition, in order to serve as the SIL 910, or to generate the partial segregation phenomenon of the group III elements (Al, Ga, and In) due to the lattice defects, the thickness of the SIL 910 may be 10 nm or more. This thickness may be a thickness for relaxing strain acting on the SIL 910.

This SIL 910 may have relaxed strain during a growth process. For example, the SIL 910 may be formed to be thicker than the SIL 410 disposed in the n-type region.

As such, since there are layers with relatively large lattices on a lower portion of the SIL 910, the SIL 910 itself is subjected to tensile strain. In this case, when the thickness of the SIL 910 exceeds a critical thickness, the lattices are broken and the strain is released. This state may be referred to as a strain-relaxed state. In this state, a form of defects, i.e., segregations of elements, may occur.

Such segregations 920 and 930 may form high-resistance layers. In other words, the segregations 920 and 930 may correspond to partial segregations of the group III elements (Al, Ga, and In). That is, the high-resistance layers 920 and 930 may be formed by artificial strain relaxation.

Hereinafter, the layers in which the segregations 920 and 930 are distributed may be referred to as high-resistance layers. Referring to FIG. 10, the segregations 920 and 930 may be distributed separately from each other. These segregations 920 and 930 may be distributed separately from each other in contact with the SIL 910.

As an example, FIG. 10 illustrates a state in which Al segregations 920 and 930 occur in contact with the SIL 910. These segregations may include the segregation 920 disposed on the edge side of the light-emitting device and the segregation 930 disposed on the inner side of the light-emitting device. The segregation 920 disposed on the edge side may relax a phenomenon of carriers being captured on the surface.

The segregations may include any one of Al, Ga, and In. For example, the high-resistance layers 920 and 930 may be formed by segregating at least one of In, Al, or Ga in contact with the SIL 910.

In this way, the high-resistance layers 920 and 930, i.e., segregations may be disposed inside a layer adjacent to the active layer 600. In this case, the high-resistance layers 920 and 930 may be disposed between the SIL 910 and the p-contact layer 800.

The high-resistance layers 920 and 930 may act as a barrier against a flow of current occurring between the n-type semiconductor layers 300 and 500 and the p-type semiconductor lavers 700 and 800. This barrier against current may serve to suppress and induce an internal current flow.

In other words, the current concentration structure 900 including the high-resistance layers 920 and 930 may act as an (injection) barrier against horizontal movement and/or vertical movement of carriers including holes (h+) and electrons (e−) inside the semiconductor structure.

This current concentration structure 900 may have an effect of increasing current density by concentrating current in an area with relatively low resistance when the same current is applied.

Since the carriers including holes (h+) and electrons (e−) combine in the active layer 600 to emit photons, the current concentration structure 900 may be advantageously disposed close to the active layer 600 unless characteristics (photon performance/current leakage) of crystal quality of the semiconductor structure deteriorate.

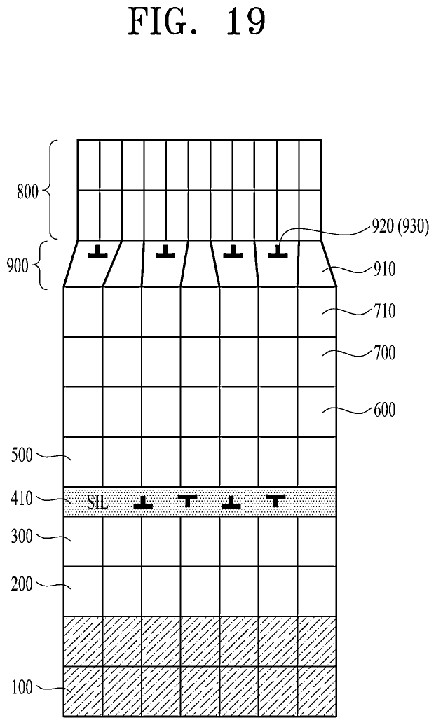

A current diffusion layer 710 may be positioned between the p-type confinement layer 700 and the current concentration structure 900 to improve characteristics of the p-type semiconductor (see FIG. 19).

The p-type contact layer 800 may include a quaternary material of AlGalnP doped with Mg as a dopant.

Other parts not described above may be the same as parts described with reference to FIGS. 1 and 2.

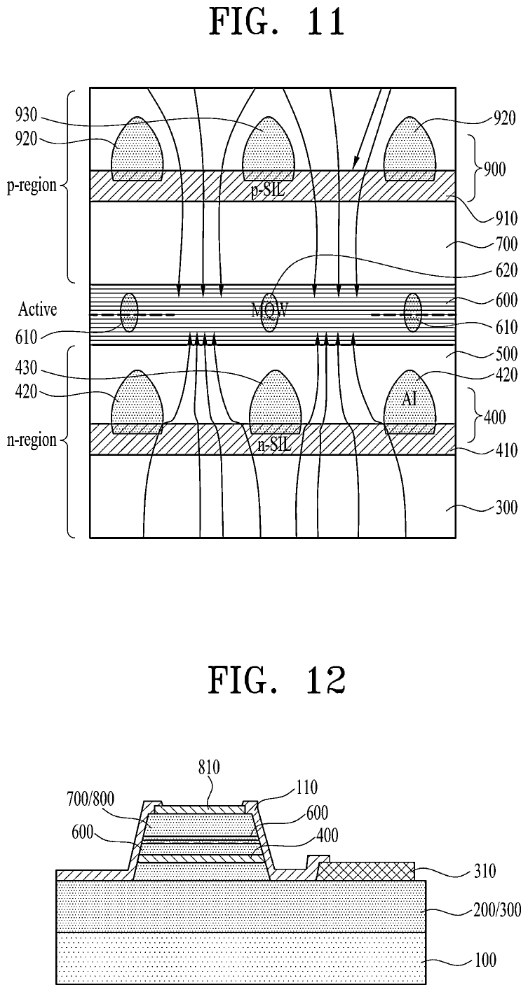

FIG. 11 is a conceptual diagram illustrating a current concentration structure of a red semiconductor light-emitting device according to another embodiment of the present disclosure.

Referring to FIG. 11, current concentration structures 610 and 620 having the characteristics described above may be disposed inside an active layer 600.

These current concentration structures 610 and 620 may be segregation structures disposed inside the active layer 600.

The current concentration structures 610 and 620 may form high-resistance layers. That is, the current concentration structures 610 and 620 may correspond to partial segregations of group III elements (Al, Ga, and In).

The current concentration structures 610 and 620 disposed inside the active layer 600 may partially include segregations of In, Ga, and Al. These segregations may exist in the form of InP, GaP, and AlP, respectively.

For example, the current concentration structures 610 and 620 disposed inside the active layer 600 may be partially formed of at least one of InP, GaP, or AlP.

FIG. 12 is a cross-sectional view illustrating an implementation example of a red semiconductor light-emitting device according to an embodiment of the present disclosure.

Referring to FIG. 12, a horizontal light-emitting device implemented including the current concentration structure 400 described above is illustrated. FIG. 12 illustrates a state including the current concentration structure 400 in an n-type region. However, as described above, it is apparent that the current concentration structures 900, 610, and 620 are applicable even to a p-type region and/or the active layer 600.

The red semiconductor light-emitting device including the current concentration structure 400 implemented as the horizontal light-emitting device includes a buffer layer 200, n-type semiconductor layers 300 and 500, an active layer 600, and p-type semiconductor layers 700 and 800, which are sequentially disposed on a substrate 100.

In this case, the n-type semiconductor layers 300 and 500 may include the n-type contact layer 300 and the n-type confinement layer 500. The current concentration structure 400 may be disposed between the n-type contact layer 300 and the n-type confinement layer 500.

For example, a portion of the n-type contact layer 300 and a structure disposed on the n-type contact layer 300 may be mesa-etched. In this case, a portion of the n-type contact layer 300 may be exposed. An n-type electrode 310 may be disposed on the exposed surface of the n-type contact layer 300.

Additionally, a p-type electrode 810 may be disposed on the p-type contact layer 800.

A passivation layer 110 may be disposed on the exposed surfaces of the n-type semiconductor layers 300 and 500, the current concentration structure 400, the active layer 600, and the p-type semiconductor layers 700 and 800.

FIG. 13 is a cross-sectional view illustrating another implementation example of a red semiconductor light-emitting device according to an embodiment of the present disclosure.

Referring to FIG. 13, a vertical light-emitting device implemented including the current concentration structure 400 described above is illustrated. FIG. 13 illustrates a state including the current concentration structure 400 in an n-type region. However, as described above, it is apparent that the current concentration structures 900, 610, and 620 are applicable even to a p-type region and/or the active layer 600.

The red semiconductor light-emitting device including the current concentration structure 400 implemented as the vertical light-emitting device includes a buffer layer 200, n-type semiconductor layers 300 and 500, an active layer 600, and p-type semiconductor layers 700 and 800, which are sequentially disposed on a substrate 100.

In this case, the n-type semiconductor layers 300 and 500 may include the n-type contact layer 300 and the n-type confinement layer 500. The current concentration structure 400 may be disposed between the n-type contact layer 300 and the n-type confinement layer 500.

As an example, the n-type contact layer 300 and a structure disposed on the n-type contact layer 300 may be mesa-etched. An n-type electrode 320 may be disposed between the n-type contact layer 300 and the substrate 100. In this case, the substrate 100 may be a transfer substrate rather than a growth substrate.

In addition, a p-type electrode 820 may be disposed on the p-type contact layer 800.

A passivation layer 110 may be disposed on the exposed surfaces of the n-type semiconductor layers 300 and 500, the current concentration structure 400, the active layer 600, and the p-type semiconductor layers 700 and 800.

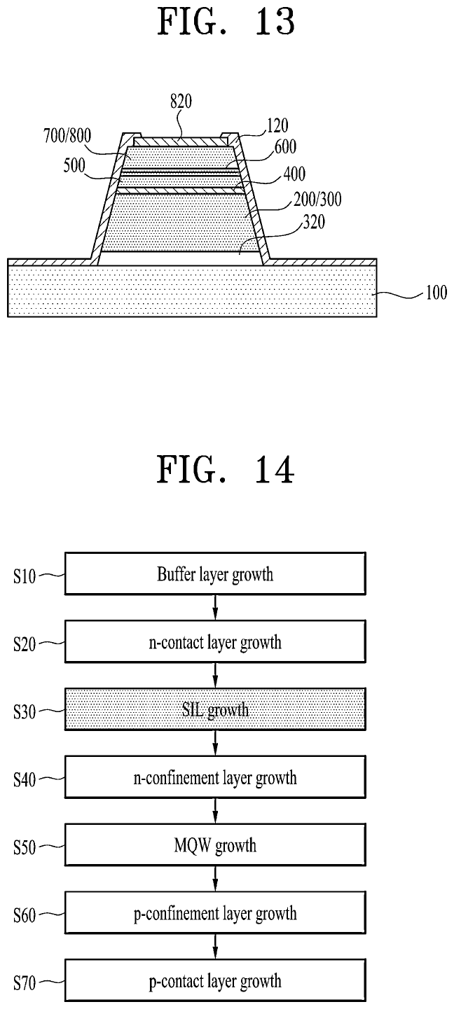

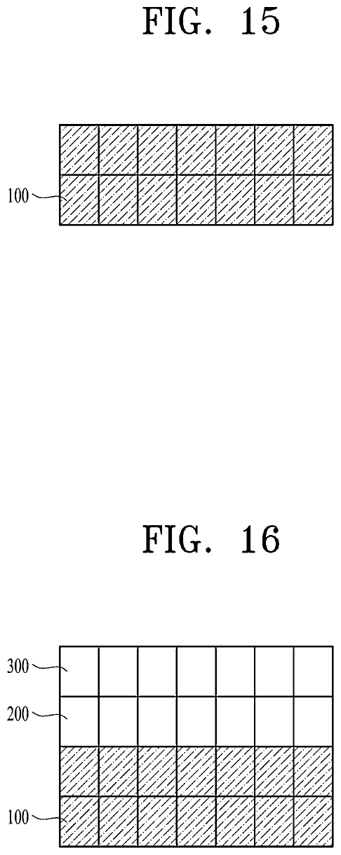

FIG. 14 is a flowchart illustrating a method of manufacturing a red semiconductor light-emitting device according to an embodiment of the present disclosure. FIGS. 15 to 19 are cross-sectional schematic diagrams illustrating a method of manufacturing a red semiconductor light-emitting device according to an embodiment of the present disclosure.

Hereinafter, a method of manufacturing the red semiconductor light-emitting device according to an embodiment of the present disclosure will be described step by step with reference to FIGS. 14 to 19. In this case, the structures of FIGS. 1 to 11 described above may be referred to together. Parts that overlap with those described above may be omitted or briefly explained in the description of this manufacturing method.

First, as illustrated in FIGS. 15 and 16, a buffer layer 200 may be formed on a substrate 100 (S10). In this case, the substrate 100 may include a gallium arsenide (GaAs) substrate. For example, the substrate 100 may be a thick GaAs substrate. Additionally, the buffer layer 200 may be a GaAs layer.

Thereafter, an n-type contact layer 300 for n-contact may be formed on the buffer layer 200 (S20).

For example, the n-type contact layer 300 may include a quaternary material of AlGaInP doped with Si as a dopant. This n-type contact layer 300 may also serve as a current diffusion layer.

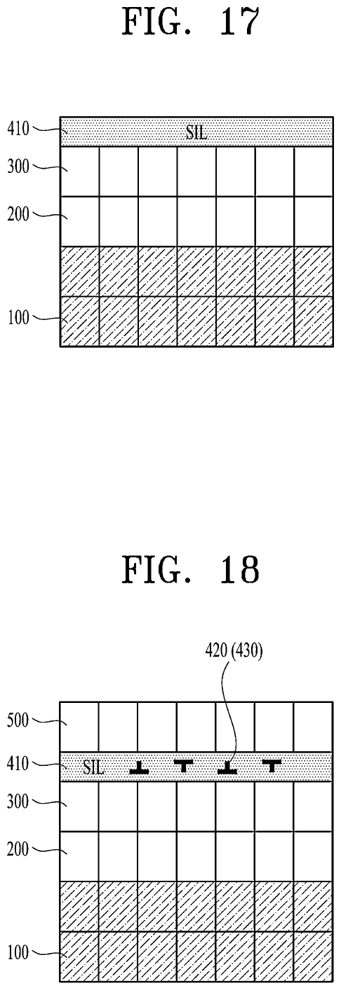

Referring to FIG. 17, an SIL 410 may be formed on the n-type contact layer 300 (S30).

The SIL 410 may include a semiconductor layer subjected to tensile strain. That is, the SIL 410 may include a layer having a relatively small lattice constant.

This SIL 410 may include (AlₓGa₁₋ₓ)_{1-y}In_{y}P. For example, the SIL 410 may be formed of a quaternary material of AlGalnP, i.e., (AlₓGa₁₋ₓ)_{1-y}In_{y}P.

In this case, the content of In, i.e., the value of y, may be less than 0.48. That is, in order to function as the SIL 410 or to generate the partial segregation phenomenon of the group III elements (Al, Ga, and In) due to lattice defects, the value of y may be less than 0.48. More specifically, the value of y may be 0.3 to 0.35.

In addition, in order to serve as the SIL 410, or to generate the partial segregation phenomenon of the group III elements (Al, Ga, and In) due to the lattice defects, the thickness of the SIL 410 may be 10 nm or more. This thickness may be a thickness for relaxing strain acting on the SIL 410.

Referring to FIG. 18, an n-type confinement layer 500 may be formed on the SIL 410 (S40).

In this case, a lattice constant of the n-type confinement layer 500 may be the same as or similar to that of the n-type contact layer 300.

In this case, as the n-type confinement layer 500 formed on the SIL 410 grows, lattice defects may occur in order to achieve lattice matching between the n-type contact layer 300, the SIL 410, and the n-type confinement layer 500. Due to these lattice defects, a partial segregation phenomenon of the group III elements (Al, Ga, and In) may occur.

As such, since there are layers with relatively large lattices on an upper portion and a lower portion of the SIL 410, the SIL 410 itself is subjected to tensile strain. In this case, when the thickness of the SIL 410 exceeds a critical thickness, the lattices are broken and the strain is released. This state may be referred to as a strain-relaxed state. In this state, a form of defects, i.e., segregations of elements, may occur.

Such segregations 420 and 430 may form high-resistance layers. In other words, the segregations 420 and 430 may correspond to partial segregations of the group III elements (Al, Ga, and In). That is, the high-resistance layers 420 and 430 may be formed by artificial strain relaxation.

Hereinafter, the layers in which the segregations 420 and 430 are distributed may be referred to as high-resistance layers. Referring to FIG. 2, the segregations 420 and 430 may be distributed separately from each other. These segregations 420 and 430 may be distributed separately from each other in contact with the SIL 410.

The segregations may include any one of Al, Ga, and In. For example, the high-resistance layers 420 and 430 may be formed by segregating at least one of In, Al, or Ga in contact with the SIL 410.

Referring to FIG. 19, an active layer 600 may be formed on the n-type confinement layer 500 (S50).

The active layer 600 may have a multi-quantum well (MQW) structure to emit red wavelength light. This active layer 600 may be formed of a quaternary material of AlGalnP, i.e., (AlₓGa₁₋ₓ)_{1-y}In_{y}P.

In this way, the high-resistance layers 420 and 430, i.e., the segregations, may be disposed inside a layer adjacent to the active layer 600. In this case, the high-resistance layers 420 and 430 may be disposed inside the n-type confinement layer 500. In other words, the high-resistance layers 420 and 430 may be disposed between the SIL 410 and the active layer 600.

These high-resistance layers 420 and 430 may act as a barrier against a flow of current occurring between the n-type confinement layer 500 and the p-type contact layer 300. This barrier against current may serve to suppress and induce an internal current flow.

A p-type confinement layer 700 may be formed on the active layer 600 (S60).

The p-type confinement layer 700 may include a ternary material of n-AlInP having a relatively large bandgap energy. This p-type confinement layer 700 may be doped with Mg as a dopant.

Optionally, a current diffusion layer 710 may be disposed on the p-type confinement layer 700 to improve the characteristics of the p-type semiconductor.

Although not shown in FIG. 14, as described above with reference to FIG. 10, an SIL 910 may be formed on the p-type confinement layer 700.

This SIL 910 may include a semiconductor layer subjected to tensile strain. That is, the SIL 910 may include a layer having a relatively small lattice constant.

For example, the lattice constant of the SIL 910 may be smaller than that of the p-type confinement layer 700.

Since the lattice constant of the SIL 910 is smaller than that of the p-type confinement layer 700, the SIL 910 may be subjected to tensile strain while growing. That is, lattice defects may occur in the SIL 910 in order to achieve lattice matching with the p-type confinement layer 700. A partial segregation phenomenon of group III elements (Al, Ga, and In) may occur due to these lattice defects.

The SIL 910 may include (AlₓGa₁₋ₓ)_{1-y}In_{y}P. For example, the SIL 910 may be formed of a quaternary material of AlGalnP, i.e., (AlₓGa₁₋ₓ)_{1-y}In_{y}P.

In this case, the content of In, i.e., the value of y, may be less than 0.48. That is, in order to function as the SIL 910 or to generate the partial segregation phenomenon of the group III elements (Al, Ga, and In) due to lattice defects, the value of y may be less than 0.48. More specifically, the value of y may be 0.3 to 0.35.

In addition, in order to serve as the SIL 910, or to generate the partial segregation phenomenon of the group III elements (Al, Ga, and In) due to the lattice defects, the thickness of the SIL 910 may be 10 nm or more. This thickness may be a thickness for relaxing strain acting on the SIL 910.

This SIL 910 may have relaxed strain during a growth process. For example, the SIL 910 may be formed to be thicker than the SIL 410 disposed in the n-type region.

As such, since there are layers with relatively large lattices on a lower portion of the SIL 910, the SIL 910 itself is subjected to tensile strain. In this case, when the thickness of the SIL 910 exceeds a critical thickness, the lattices are broken and the strain is released. This state may be referred to as a strain-relaxed state. In this state, a form of defects, i.e., segregations of elements, may occur.

Such segregations 920 and 930 may form high-resistance layers. In other words, the segregations 920 and 930 may correspond to partial segregations of the group III elements (Al, Ga, and In). That is, the high-resistance layers 920 and 930 may be formed by artificial strain relaxation.

Hereinafter, the layers in which the segregations 920 and 930 are distributed may be referred to as high-resistance layers. Referring to FIG. 10, the segregations 920 and 930 may be distributed separately from each other. These segregations 920 and 930 may be distributed separately from each other in contact with the SIL 910.

In this way, the SIL 910 and the high-resistance layers in which the segregations are distributed may constitute a current concentration structure 900.

Thereafter, a p-type contact layer 800 may be formed on the current concentration structure 900 (S70).

The p-type contact layer 800 may have a smaller lattice constant than the SIL 910. For example, the lattice constant of the p-type contact layer 800 may be smaller than that of the p-type confinement layer 700. This p-type contact layer 800 may include, for example, a material of GaP.

In this way, the high-resistance layers 920 and 930, i.e., segregations, may be disposed inside a layer adjacent to the active layer 600. In this case, the high-resistance layers 920 and 930 may be disposed between the SIL 910 and the p-contact layer 800.

These high-resistance layers 920 and 930 may act as a barrier against a flow of current occurring between the n-type semiconductor layers 300 and 500 and the p-type semiconductor layers 700 and 800. This barrier against current may serve to suppress and induce an internal current flow.

In other words, the current concentration structure 900 including the high-resistance layers 920 and 930 may act as an (injection) barrier against horizontal movement and/or vertical movement of carriers including holes (h+) and electrons (e−) inside the semiconductor structure.

This current concentration structure 900 may have an effect of increasing current density by concentrating current in an area with relatively low resistance when the same current is applied.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL APPLICABILITY

According to the present disclosure, a red semiconductor light-emitting device usable in a display using a micro-LED and a method of manufacturing the same may be provided.

1. A red light-emitting semiconductor light-emitting device, comprising:
a substrate;
a buffer layer disposed on the substrate;
a first conductive contact layer disposed on the buffer layer;
a first conductive confinement layer disposed on the first conductive contact layer;
an active layer disposed on the first conductive confinement layer;
a second conductive confinement layer disposed on the active layer;
a second conductive contact layer disposed on the second conductive confinement layer; and
a current concentration structure disposed at least one side between the first conductive contact layer and the first conductive confinement layer or between the second conductive contact layer and the second conductive confinement layer,
wherein the current concentration structure includes:
a strain induced layer; and
high-resistance layers that contact the strain induced layer and are distributed separately from each other to form a current barrier.

2. The red light-emitting semiconductor light-emitting device of claim 1, wherein the strain induced layer includes a semiconductor layer subjected to tensile strain.

3. The red light-emitting semiconductor light-emitting device of claim 1, wherein the strain induced layer includes a material of (AlₓGa₁₋ₓ)_{1-y}In_{y}P.

4. The red light-emitting semiconductor light-emitting device of claim 3, wherein y is less than 0.48.

5. The red light-emitting semiconductor light-emitting device of claim 1, wherein the strain induced layer has a thickness of 10 nm or more.

6. The red light-emitting semiconductor light-emitting device of claim 1, wherein the high-resistance layers include a segregation structure.

7. The red light-emitting semiconductor light-emitting device of claim 1, wherein the segregation includes any one of aluminum (Al), gallium (Ga), and indium (In).

8. The red light-emitting semiconductor light-emitting device of claim 1, wherein the high-resistance layers are formed by segregating at least one of indium (In), aluminum (Al), or gallium (Ga) in contact with the strain induced layer.

9. The red light-emitting semiconductor light-emitting device of claim 1, wherein the segregation is disposed inside a layer adjacent to the active layer.

10. The red light-emitting semiconductor light-emitting device of claim 1, wherein the high-resistance layers are formed by artificial strain relaxation.

11. The red light-emitting semiconductor light-emitting device of claim 1, wherein the high-resistance layers are further included in the active layer.

12. The red light-emitting semiconductor light-emitting device of claim 1, wherein the current concentration structure is disposed adjacent to the active layer.

13. A method of manufacturing a red light-emitting semiconductor light-emitting device, comprising:
forming a buffer layer on a substrate;
forming a first conductive contact layer on the buffer layer;
forming a first strain induced layer on the first conductive contact layer, a lattice constant of the first strain induced layer being different from a lattice constant of the first conductive contact layer;
forming a first high-resistance layer in contact with the first strain induced layer by forming a first conductive confinement layer on the first strain induced layer, the first conductive confinement layer having a lattice constant that applies strain to the first strain induced layer;
forming an active layer on the first conductive confinement layer;
forming a second conductive confinement layer on the active layer; and
forming a second conductive contact layer on the second conductive confinement layer.

14. The method of claim 13, further comprising forming a second strain induced layer on the second conductive confinement layer.

15. The method of claim 14, wherein the second strain induced layer is formed to have a strain critical thickness or more to form a second high-resistance layer in contact with the second strain induced layer.

16. The method of claim 14, wherein the second conductive contact layer has a smaller lattice constant than the second strain induced layer.

17. The method of claim 14, further comprising forming a current diffusion layer between the second conductive confinement layer and the second strain induced layer.

18. The method of claim 14, wherein at least one of the first strain induced layer or the second strain induced layer includes a semiconductor layer subjected to tensile strain.

19. The method of claim 14, wherein at least one of the first strain induced layer or the second strain induced layer includes a material of (AlₓGa₁₋ₓ)_{1-y}In_{y}P.

20. The method of claim 15, wherein at least one of the first high-resistance layer or the second high-resistance layer includes a segregation structure.
